(19) United States
(12) Patent Application Publication
(10) Pub. No.: US 2014/0197462 A1
(43) Pub. Date: Jul. 17, 2014

(54) III-Nitride Transistor with High Resistivity Substrate

(71) Applicant: International Rectifier Corporation, El Segundo, CA (US)

(72) Inventor: Michael A. Briere, Scottsdale, AZ (US)

(73) Assignee: International Rectifier Corporation, El Segundo, CA (US)

(21) Appl. No.: 14/188,316

(22) Filed: Feb. 24, 2014

Related U.S. Application Data
(63) Continuation-in-part of application No. 14/140,222, filed on Dec. 24, 2013.
(60) Provisional application No. 61/772,102, filed on Mar. 4, 2013.
(60) Provisional application No. 61/752,258, filed on Jan. 14, 2013.

(51) Int. Cl. H01L 29/778; H01L 29/20

(52) U.S. Cl. CPC H01L 29/778; H01L 29/2003
USPC 257/194

(57) ABSTRACT

There are disclosed herein various implementations of semiconductor structures including high resistivity substrates. In one exemplary implementation, such a semiconductor structure includes a substrate having a resistivity of greater than or approximately equal to one kiloohm-centimeter (1 kΩ-cm), and a III-N high electron mobility transistor (HEMT) having a drain, a source, and a gate, fabricated over the substrate. The III-N HEMT is configured to produce a two-dimensional electron gas (2 DEG). The resistivity of the substrate reduces the capacitive coupling of the 2 DEG to the substrate. In one implementations, a spatially confined dielectric region is formed in the substrate, under at least one of the drain and the source.

The present application claims the benefit of and priority to a provisional application entitled “III-N Transistor with High Resistivity Substrate,” Ser. No. 61/772,102 filed on Mar. 4, 2013. In addition, the present application is a continuation-in-part of application Ser. No. 14/140,222, entitled “Semiconductor Structure Including a Spatially Confined Dielectric Region,” filed on Dec. 24, 2013, which in turn claims priority to provisional application Ser. No. 61/752,258, entitled “III-Nitride Transistor Including Spatially Defined Buried Dielectric,” and filed on Jan. 14, 2013. The disclosures in the above-referenced patent applications are hereby incorporated fully by reference into the present application. Moreover, the present application claims priority to each one of the patent applications identified above.

### BACKGROUND

I. Definition As used herein, “III-Nitride” or “III-N” refers to a compound semiconductor that includes nitrogen and at least one group III element such as aluminum (Al), gallium (Ga), indium (In), and boron (B), and including but not limited to any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{(1-a-b)}), for example. III-N also refers generally to any polarity including but not limited to Ga-polar, N-polar, semi-polar, or non-polar crystal orientations. A III-N material may also include either the Wurtzitic, Zincblende, or mixed polytypes, and may include single-crystal, monocrystalline, polycrystalline, or amorphous structures. Gallium nitride or GaN, as used herein, refers to a III-N compound semiconductor wherein the group III element or elements include some or a substantial amount of gallium, but may also include other group III elements in addition to gallium. A III-N or a GaN transistor may also refer to a composite high voltage enhancement mode transistor that is formed by connecting the III-N or the GaN transistor in cascode with a lower voltage group IV transistor.

In addition, as used herein, the phrase “group IV” refers to a semiconductor that includes at least one group IV element such as silicon (Si), germanium (Ge), and carbon (C), and may also include compound semiconductors such as silicon germanium (SiGe) and silicon carbide (SiC), for example. Group IV also refers to semiconductor materials which include more than one layer of group IV elements, or doping of group IV elements to produce strained group IV materials, and may also include group IV based composite substrates such as silicon on insulator (SOI), separation by implantation of oxygen (SIMOX) process substrates, and silicon on sapphire (SOS), for example.

II. Background Art

III-N materials are semiconductor compounds that have relatively wide direct bandgaps and can have strong piezoelectric polarizations, which can enable high breakdown fields, high saturation velocities, and the creation of two-dimensional electron gases (2 DEGs). As a result, III-N materials are suitable for use in many microelectronic applications as field-effect transistors (FETs), including heterostructure FETs (HFETs) such as high electron mobility transistors (HEMTs).

Although the III-Nitrides are known as wide bandgap materials, they also have relatively high dielectric constants compared to silicon oxide (SiO₂). For example, gallium nitride (GaN) has a dielectric constant of approximately 9.5, and aluminum nitride (AlN) has a dielectric constant of approximately 9.1, compared to a dielectric constant of approximately 3.9 for SiO₂. As a result, when III-N based FETs are employed for high voltage and high speed switching applications, the parasitic capacitance across the underlying III-N material layers down to the device substrate can contribute to slower switching times and higher charge for a given voltage. Consequently, the increased parasitic capacitance between the drain or source of the FET and the FET substrate can have undesirable consequences for its high voltage and high speed switching performance.

### SUMMARY

The present disclosure is directed to a III-Nitride transistor with high resistivity substrate, substantially as shown in and/or described in connection with at least one of the figures, and as set forth more completely in the claims.

### BRIEF DESCRIPTION OF THE DRAWINGS

FIG. 1 shows a cross-sectional view of a conventional field-effect transistor (FET) structure.

FIG. 2 shows a cross-sectional view of an exemplary FET structure with a high resistivity substrate, according to one implementation.

FIG. 3A shows a top view of an exemplary FET structure with a high resistivity substrate including multiple spatially confined dielectric regions, according to one implementation.

FIG. 3B shows a cross-sectional view of the exemplary FET structure with a high resistivity substrate of FIG. 3A.

FIG. 4 shows a cross-sectional view of an exemplary FET structure with a high resistivity substrate including multiple spatially confined dielectric regions, according to another implementation.

### DETAILED DESCRIPTION

The following description contains specific information pertaining to implementations in the present disclosure. One skilled in the art will recognize that the present disclosure may be implemented in a manner different from that specifically discussed herein. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

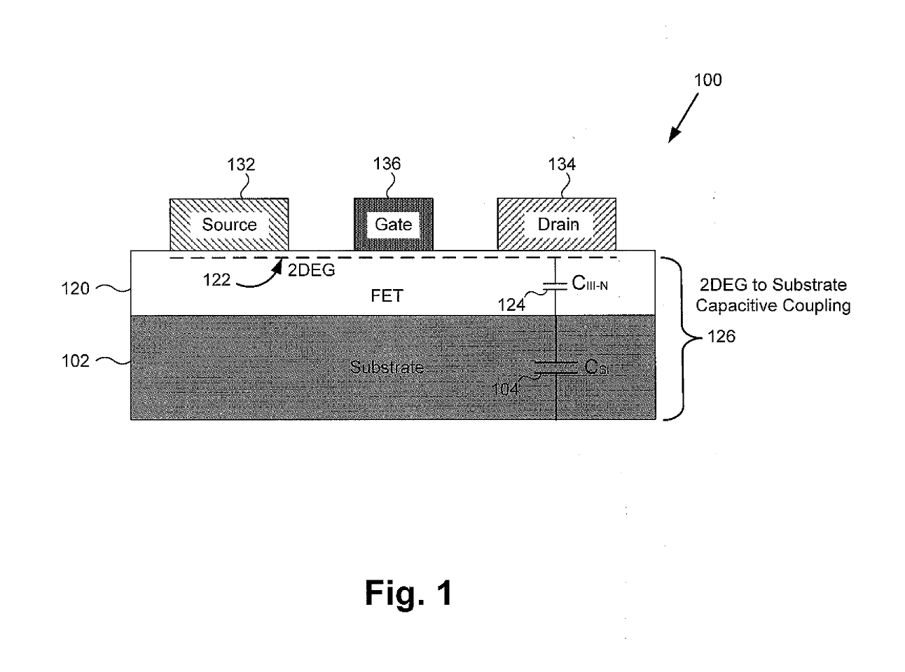

FIG. 1 shows a cross-sectional view of conventional field-effect transistor (FET) structure 100. Conventional FET structure 100 includes FET 120 fabricated over substrate 102. As shown in FIG. 1, FET 120 includes source 132, drain 134, and gate 136. According to the example shown in FIG. 1, FET 120 is implemented as a III-N heterostructure FET (HFET), in the form of a III-N high electron mobility transistor (HEMT) fabricated over substrate 102 and configured to produce two-dimensional electron gas (2 DEG) 122. It is noted that substrate 102 may be a group IV substrate, such as a silicon substrate for example.

As is the case for substantially all HFET structures, there are several regions of capacitive coupling between the various effective device terminals across conventional FET structure 100. FIG. 1 shows one such parasitic capacitive coupling 126 of 2 DEG 122 or drain 134 of FET 120 to substrate 102 and depicted as the combination of C_{III-N} 124 and C_{Si} 104. It is noted that although not explicitly represented in FIG. 1, there may also be other analogous parasitic capacitances associated with conventional FET structure 100. Nevertheless, in many implementations, such as when source 132 of FET 120 is tied to substrate 102, the 2 DEG-to-substrate or drain-to-substrate parasitic capacitance represented by capacitive coupling 126 is typically of special concern.

As stated above, although III-N materials are known as wide bandgap materials, they also have relatively high dielectric constants compared to silicon oxide (SiO₂). For example and as also noted above, gallium nitride (GaN) has a dielectric constant of approximately 9.5, and aluminum nitride (AlN) has a dielectric constant of approximately 9.1, which may be compared to a dielectric constant of approximately 3.9 for SiO₂. When III-N based FETs, such as FET 120, are employed for high voltage switching applications, the parasitic capacitance across the underlying III-N epitaxial layers of FET 120 down to substrate 102 and represented as capacitive coupling 126, can contribute to slower switching times and higher switching charge for a given voltage. As a result, the 2 DEG-to-substrate or drain-to-substrate capacitance represented by capacitive coupling 126 can have undesirable consequences for the high voltage switching (speed as well as charge) performance of FET 120.

One solution for reducing the parasitic capacitance represented by capacitive coupling 126 is to increase the thickness of the III-N layers used in FET 120. However, in large scale manufacturing of semiconductor switches, large diameter substrates are typically employed. The thickness of the III-N layers formed on large diameter substrates is typically limited by the stresses produced in the III-N material used to form FET 120, as well as the stresses produced in substrate 102.

The stresses produced in FET structure 100 may be due to mismatch of the lattice constants and/or mismatch of the coefficients of thermal expansion between the III-N layers used in FET 120 and the silicon or other typically non-native (i.e., non-III-N) materials used to provide substrate 102. Those stresses can lead to excessive warp and bow of substrate 102, or to cracking of the III-N layers of FET 120. Consequently, there is a need for an alternative solution for reducing the parasitic capacitance represented by capacitive coupling 126 that does not require a substantial increase in the thickness of the III-N layers used to form FET 120 for a given voltage rating.

In the conventional art, the various approaches developed to increase the breakdown voltage of FET 120 without increasing the thickness of its III-N layers suffer from other performance drawbacks. For example, one such approach uses locally etched backside substrate removal under source 132 and/or drain 134 of FET 120. Although this technique may increase the breakdown voltage of FET 120, it can adversely result in the poor thermal characteristics and unstable surface conditions.

A second technique used is the formation of P-N junctions in substrate 102 under drain 134 and/or source 132 of FET 120. However this approach typically leads to leaky P-N junctions, particularly at high temperatures, and may also result in relatively high substrate coupling capacitance. Thus, there remains a need for an alternative approach to forming III-N FETs which exhibit fast switching times and reduced charge, while maintaining stable high voltage, high temperature performance, with reduced parasitic capacitance to the substrate.

The present application is directed to III-N FETs configured to have reduced capacitance and switching losses, and suitable for use as high-voltage transistors in transient-event type operation. It is noted that for high voltage applications, the III-N FETs typically see transient type events rather than direct current (DC) type events. As a result, the capacitive coupling is primarily transient in nature, rather than DC. Consequently, and as disclosed herein, III-N FETs having desirable performance characteristics may be provided through the use of high resistivity substrates.

By utilizing a high resistivity substrate, the solutions disclosed herein reduce the capacitive coupling between the 2 DEG or drain of a III-N HEMT, for example, and the substrate over which the HEMT is fabricated. Consequently, the switching time of the HEMT or other type of FET may be reduced. That is to say, use of a high resistivity substrate, as disclosed herein, can provide the benefits of an insulator in the short term (e.g., nanoseconds) for transients including voltage spikes, as well as delivering benefits in the long term (e.g., microseconds) for switching events. Moreover, in some implementations, further improvements in performance may be achieved through the use of one or more spatially confined dielectric regions formed in the high resistivity substrate, under the FET drain and/or the FET source.

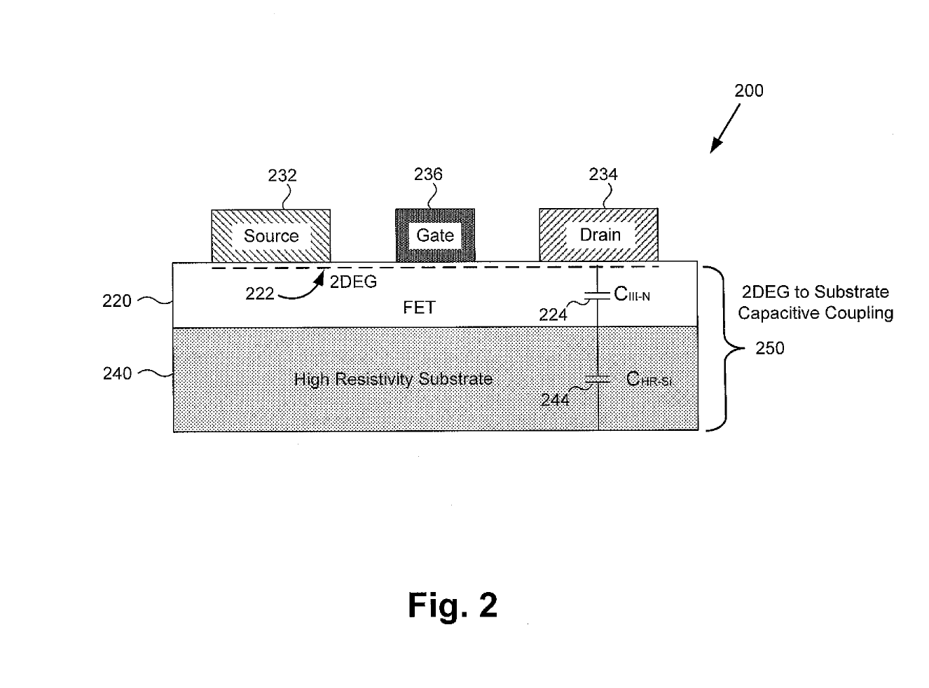

Referring to FIG. 2, FIG. 2 shows a cross-sectional view of an exemplary FET structure with a high resistivity substrate, according to one implementation. FET structure 200 includes FET 220 fabricated over high resistivity substrate 240. As shown in FIG. 2, FET 220 includes source 232, drain 234, and gate 236, as well as 2 DEG 222. As further shown in FIG. 2, FET 220 may be implemented as a III-N HFET, such as a III-N HEMT, fabricated over high resistivity substrate 240 and configured to produce 2 DEG 222.

According to the present exemplary implementation high resistivity substrate 240 takes the form of a high resistivity silicon (HR-Si) substrate. High resistivity substrate 240 may have a resistivity of greater than one kiloohm-centimeter (1.0 kΩ-cm), for example. In one implementation, for instance, high resistivity substrate 240 may have a resistivity in a range from approximately one kiloohm-centimeter to approximately ten kiloohm-centimeters (1.0 kΩ-cm-10 kΩ-cm), or in a range from approximately one kiloohm-centimeter to approximately fifty kiloohm-centimeters (1.0 kΩ-cm-50 kΩ-cm). Also shown in FIG. 2 is capacitive coupling 250 of 2 DEG 222 or drain 234 of FET 220 to high resistivity substrate 240, which is depicted as the combination of the III-N parasitic capacitance C_{III-N} 224 and the HR-Si parasitic capacitance C_{HR-Si} 244.

Although the present implementation describes high resistivity substrate 240 as an HR-Si substrate, more generally, high resistivity substrate 240 may be formed using other group IV materials (e.g., SiC, Ge, SiGe, and the like). High resistivity substrate 240 may be single crystal or polycrystalline, or may be formed as a composite substrate. Moreover, as used in the present application, “silicon substrate” may refer to any substrate that includes a silicon surface. Examples of suitable silicon substrates include substrates that are formed substantially entirely of silicon, and silicon-on-sapphire substrates (SOS), among others. Suitable silicon substrates also include composite substrates that have a silicon wafer bonded to another material such as diamond, AlN, or other polycrystalline materials. In some implementations, silicon substrates having different crystallographic orientations may be used. In some cases, for example, silicon (111) substrates may be preferred for high resistivity substrate 240. In other cases, silicon (100) or (110) substrates may be preferred for high resistivity substrate 240.

FET 220 may include multiple III-N layers. For example, FET 220 may include one or more III-N transition layers and/or a buffer layer formed over high resistivity substrate 240. In addition, FET 220 includes at least one active layer. In one implementation, as shown in FIG. 2, FET 220 may be a HEMT including a III-N heterostructure formed over the transition and/or buffer layers formed over high resistivity substrate 240. The III-N heterostructure may include an aluminum gallium nitride (AlGaN) or other III-N barrier layer formed over a GaN or other III-N channel layer and give rise to 2 DEG 222. In some implementations, the III-N heterostructure may further include one or more capping and/or passivation layers formed over the III-N barrier layer.

It is noted that HR-Si parasitic capacitance C_{HR Si} 244 is less than the parasitic capacitance C_{Si} 104 of conventional FET structure 100, in FIG. 1 (i.e., C_{HR Si}<C_{Si}). Consequently, use of high resistivity substrate 240 as a support substrate for fabrication of FET 220 reduces capacitive coupling 250 between 2 DEG 222 or drain 234 of FET 220 and high resistivity substrate 240 for a given voltage. Such a reduction in capacitive coupling 250, in turn, advantageously results in reduced switching time for FET 220. Thus, use of high resistivity substrate 240 in FET structure 200 can provide the benefits of an insulator in the short term (e.g., nanoseconds) for transients including voltage spikes, and further provides benefits in the long term (e.g., microseconds) for switching events.

It is further noted that although the exemplary implementation shown in FIG. 2 is described in terms of the reduction in 2 DEG-to-substrate or drain-to-substrate capacitive coupling 250, the presence of high resistivity substrate 240 under source 232 also serves to reduce the source-to-substrate capacitive coupling of FET 220. As a result, the resistivity of high resistivity substrate 240 reduces the capacitive coupling of one or both of drain 234 and source 232, to high resistivity substrate 240.

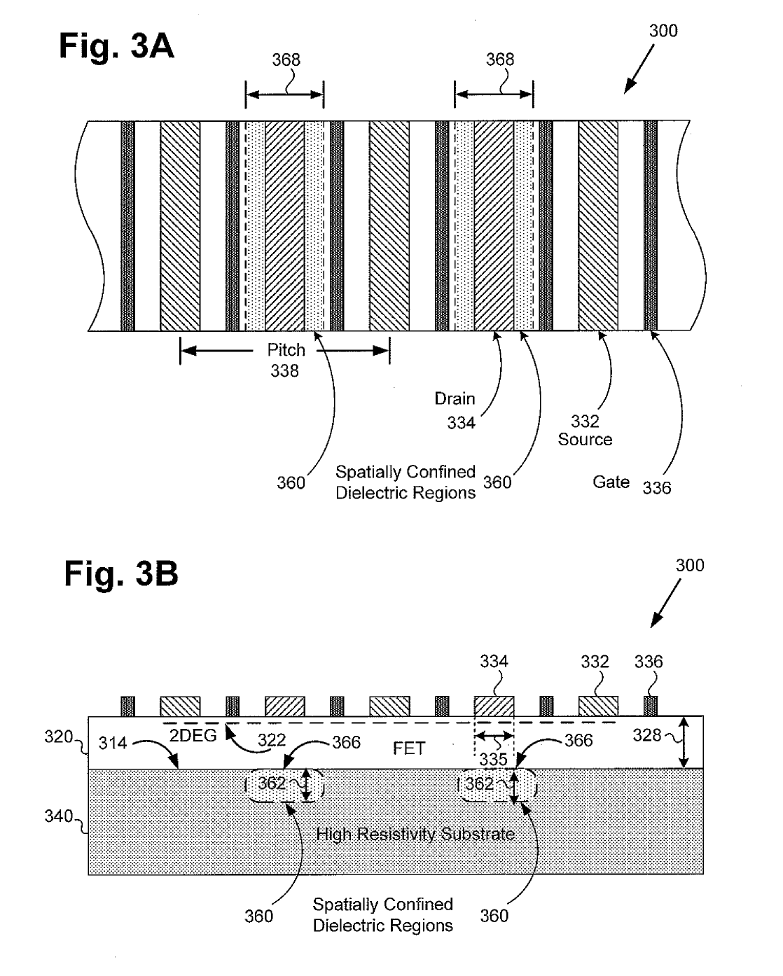

Continuing to FIGS. 3A and 3B, FIG. 3A shows a top view of exemplary FET structure 300 with a high resistivity substrate and including multiple spatially confined dielectric regions 360, while FIG. 3B shows a cross-sectional view of exemplary FET structure 300. As shown in FIG. 3B, FET structure 300 includes FET 320 fabricated over high resistivity substrate 340. As shown in FIGS. 3A and 3B, FET 320 includes source regions 332, drain regions 334, gates 336, and 2 DEG 322, and is fabricated over major surface 314 of high resistivity substrate 340. FIG. 3B also shows thickness 362 and top sides 366 of spatially confined dielectric regions 360, while FIG. 3A shows width 368 of spatially confined dielectric regions 360, and pitch 338 of FET 320, i.e., the distance between the centers of immediately adjacent, or neighboring, source regions 332. In addition, the width of a drain contact (or source contact) of FET 320 is conceptually represented by interval 335, and the thickness of the III-N layers used to produce FET 320 is represented as thickness 328, in FIG. 3B.

Although not shown in FIGS. 3A and 3B in the interests of conceptual clarity, it is noted that FET structure 300 may include additional overlying layers including passivation and insulating layers, field plates (source, gate, and drain), as well as metal bond pads, traces, and interconnect vias. High resistivity substrate 340, and FET 320 including source regions 332, drain regions 334, gates 336, and 2 DEG 322 correspond respectively to high resistivity substrate 240, and FET 220 including source region 232, drain region 234, gate 236, and 2 DEG 222, in FIG. 2, and may share any of the characteristics attributed to those corresponding features, above.

As shown in FIGS. 3A and 3B spatially confined dielectric regions 360 are centered under respective drain regions 334 and extend laterally toward gates 336 in both directions. Spatially confined dielectric regions 360 may be formed of SiO₂, for example, and may be formed in high resistivity substrate 340 through oxygen implantation of high resistivity substrate 340. For example, oxygen may be implanted into high resistivity silicon substrate 340 at a concentration of approximately 1×10¹⁸/cm². There are several methodologies which may be used to form spatially confined dielectric regions 360, including diffusion of oxygen, wafer bonding, and silicon lateral overgrowth techniques, among others. However, in some implementations it may be advantageous or desirable to use separation by implantation of oxygen (SIMOX).

Spatially confined dielectric regions 360 may be formed either prior to growth of the III-N epitaxial layers of FET 320 over high resistivity substrate 340, or may be substantially concurrently formed during the growth of those III-N epitaxial layers. Thus, in some implementations, the elevated growth temperatures needed for formation of the III-N epitaxial layers of FET 320 may be utilized to cause the silicon in the vicinity of the implanted oxygen to be consumed, thereby forming spatially confined dielectric regions 360 of SiO₂. For example, spatially confined dielectric regions 360 may be located below major surface 314 of silicon high resistivity substrate 340 such that there is a substantially uniform layer of silicon at major surface 314, as may be required for III-N epitaxial nucleation. However, while the III-N material of FET 320 is being formed at high temperature, spatially confined dielectric regions 360 may grow or expand towards major surface 314 of high resistivity substrate 340 such that top sides 366 of spatially confined dielectric regions 360 interface with the III-N material of FET 320.

As shown in FIGS. 3A and 3B, in some implementations, spatially confined dielectric regions 360 are substantially centered under drains 334. Moreover, spatially confined dielectric regions 360 may by laterally confined in a plane substantially parallel to major surface 314 of high resistivity substrate 340. Spatially confined dielectric regions 360 may be buried dielectric regions within high resistivity substrate 340, or may extend vertically within high resistivity substrate 340 to major surface 314. In other words; in some implementations, all sides of spatially confined dielectric regions 360 may be surrounded by high resistivity substrate 340, while in other implementations, top sides 366 of spatially confined dielectric regions 360 may not be covered by high resistivity substrate 340, as shown in FIG. 3B.

Although spatially confined dielectric regions 360 can be formed of SiO₂, as described above, other dielectrics may also be used. For example, in silicon semiconductor manufacturing, low dielectric constant (low-κ) dielectrics have been utilized to reduce parasitic capacitance between various semiconductor layers. As used herein, a low-κ dielectric refers to a dielectric material having a dielectric constant less than that of silicon SiO₂. As noted above, the dielectric constant of SiO₂ is approximately 3,9. Thus, low-κ dielectrics, such as carbon doped or fluorine doped SiO₂, among other low-κ dielectrics, can be used to form spatially confined dielectric regions 360.

Thickness 362 of spatially confined dielectric regions 360 depends partly on the voltage range of 320. For example, in various implementations, thickness 362 of spatially confined dielectric regions 360 may be in a range from approximately 0.1 μm to approximately 3.0 μm.

Formation of spatially confined dielectric regions 360 results in an equivalent circuit in which a parasitic capacitance produced by each of spatially confined dielectric regions 360 is coupled in series with the parasitic capacitance produced by the III-N layers of FET 320. As a result, the addition of the parasitic capacitance produced by each of spatially confined dielectric regions 360 in series with the parasitic capacitance produced by the III-N layers of FET 320 advantageously reduces overall 2 DEG-to-substrate or drain-to-substrate capacitive coupling for a given voltage. Consequently, the presence of spatially confined dielectric regions 360 in high resistivity substrate 340 and under drains 334 of FET 320 improves the switching time and charge performance of FET 320.

It is noted that although the exemplary implementation shown in FIGS. 3A and 3B depicts spatially confined dielectric regions 360 as being formed under drains 334 of FET 320, in other implementations spatially confined dielectric regions 360 may be formed under sources 332 of FET 320, or under both drains 334 and sources 332 of FET 320. In implementations in which spatially confined dielectric regions 360 are formed in high resistivity substrate 340 under sources 332, spatially confined dielectric regions 360 reduce a capacitive coupling of sources 332 to high resistivity substrate 340. Moreover, in implementations in which spatially confined dielectric regions 360 are formed in high resistivity substrate 340 under both drains 334 and sources 332, spatially confined dielectric regions 360 reduce the capacitive coupling of both drains 334 and sources 332 to high resistivity substrate 340.

It is further noted that although spatially confined dielectric regions 360 need not be formed so as only to underlie drains 334 and/or sources 332 of FET 320, those implementations confer advantages with regard to dissipation of heat produced by FET 320. The presence of a buried dielectric material in high resistivity substrate 340 can have the undesired consequence of obstructing the thermal path between FET 320, where heat is generated, and the bottom of high resistivity substrate 340, where heat is typically extracted. Consequently, use of spatially confined dielectric regions 360, rather than a continuous dielectric layer, enables the advantages resulting from reduction of the capacitive coupling of 2 DEG 322 or drains 334, and/or sources 332, to high resistivity substrate 340 described above, while concurrently enabling the use of conventional thermal management techniques to provide efficient heat management for FET 320. In some implementations, it may be advantageous or desirable to determine width 368 of spatially confined dielectric regions 360 based on pitch 338 of FET 320. For example, in one implementation, it may be advantageous or desirable to restrict width 368 to less then approximately one half (0.5) times pitch 338 of FET 320. In other implementations, it may be advantageous or desirable to determine width 368 of spatially confined dielectric regions 360 based on thickness 328 of the III-N layers used to form FET 320, as well as on interval 335 corresponding to the width of the drain contacts (and/or source contacts) formed on FET 320. For example, it may be advantageous or desirable to restrict width 368 of spatially confined dielectric regions 360 to less than approximately one or two times thickness 328, plus interval 335. As a specific example, in various implementations, width 368 of spatially confined dielectric regions 360 may lie in a range from approximately 5 μm to approximately 30 μm.

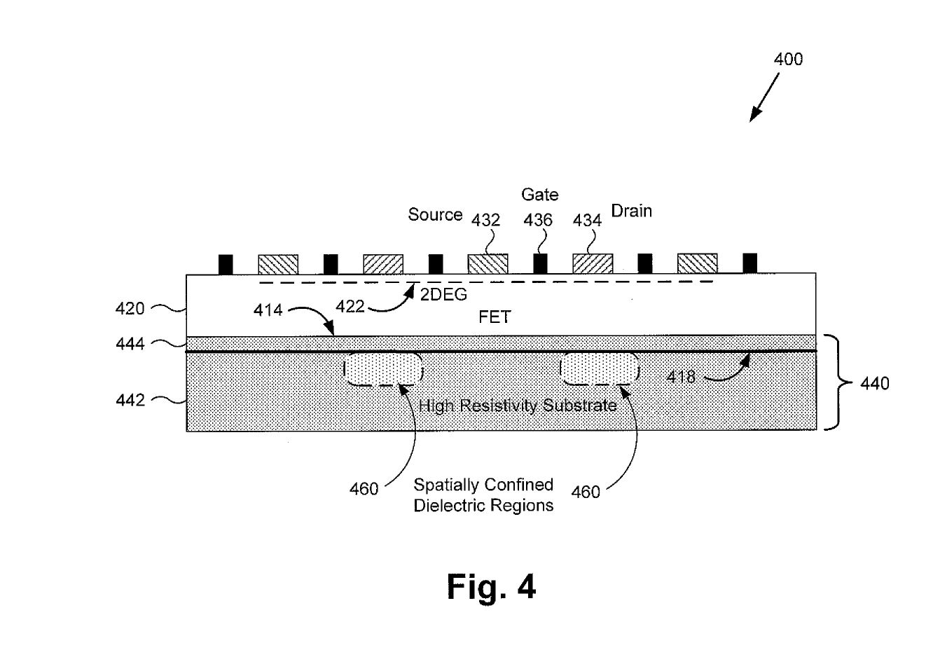

FIG. 4 shows a cross-sectional view of an exemplary FET structure with a high resistivity substrate including multiple spatially confined dielectric regions, according to another implementation. FET structure 400 includes FET 420 fabricated over high resistivity composite substrate 440. As shown in FIG. 4, FET 420 includes source regions 432, drain regions 434, gates 436, and 2 DEG 422, and is fabricated over major surface 414 of high resistivity composite substrate 440. As further shown in FIG. 4, high resistivity composite substrate 440 includes first substrate layer 442 having spatially confined dielectric regions 460 formed therein, and second substrate layer 444 formed over first substrate layer 442 and under FET 420. FET 420 including source regions 432, drain regions 434, gates 436, and 2 DEG 422 corresponds in general to FET 220 including source 232, drain 234, gate 236, and 2 DEG 222, in FIG. 2. Moreover, spatially confined dielectric regions 460, in FIG. 4, correspond to spatially confined dielectric regions 360, in FIGS. 3A and 3B, and may share any of the characteristics attributed to that corresponding feature above.

Spatially confined dielectric islands or regions 460 may be formed at top surface 418 of first substrate layer 442 of high resistivity composite substrate 440. Silicon epitaxy with lateral overgrowth may then be used to re-grow silicon for second substrate layer 444 between and above spatially confined dielectric regions 460 and top surface 418 of first substrate layer 442. Planarization using standard chemical mechanical polishing (CMP) techniques may then be performed at a top surface of second substrate layer 444 to provide major surface 414 of high resistivity composite substrate 440. In some implementations, a thin final epitaxial layer of silicon may be grown over the CMP surface to form major surface 414 of high resistivity composite substrate 440 as a III-N ready surface. As a result, and as shown in FIG. 4, in some implementations, all sides of spatially confined dielectric regions 460 may be surrounded by high resistivity composite substrate 440.

In addition to improving the coupling capacitance of the 2 DEG 422 or drains 434, and/or sources 432 to the substrate, spatially confined dielectric regions 460 and/or high resistivity composite substrate 440 can improve the standoff voltage capability of FET 420 for a given III-N epitaxial layer thickness. This has the additional benefit of a reduction in the thickness of the III-N epitaxial layer required in FET 420 to support a given standoff voltage. Because the present concepts permit use of thinner III-N layers to support a given standoff voltage, those concepts further enable use of larger diameter wafers for fabrication of FETs 220/320/420, and/or increased epitaxial deposition throughput.

Thus, by utilizing a high resistivity substrate, the solutions disclosed herein reduce the capacitive coupling between the 2 DEG or drain of a III-N HEMT or other type of FET, and the substrate over which the FET is fabricated. Consequently, the switching time of the HEMT or other type of FET may be reduced. As a result, use of a high resistivity substrate, as disclosed herein, can provide the benefits of an insulator in the short term (e.g., nanoseconds) for transients including voltage spikes, as well as delivering benefits in the long term (e.g., microseconds) for switching events. Moreover, in some implementations, further improvements in performance may be achieved through the use of one or more spatially confined dielectric regions formed in the high resistivity substrate, under the FET drain and/or the FET source.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the spirit and the scope of those concepts. As such, the described implementations are to be considered in all respects as illustrative and not restrictive. It should also be understood that the present application is not limited to the particular implementations described herein, but many rearrangements, modifications, and substitutions are possible without departing from the scope of the present disclosure.

1. A semiconductor structure comprising:
a substrate having a resistivity of greater than or approximately equal to one kiloohm-centimeter (1 kΩ-cm);
a III-N high electron mobility transistor (HEMT) including a source, a drain, and a gate, fabricated over said substrate, said III-N HEMT configured to produce a two-dimensional electron gas (2 DEG);
a spatially confined dielectric region formed in said substrate, under at least one of said drain and said source.

2. The semiconductor structure of claim 1, wherein said resistivity of said substrate is in a range from approximately 1 kΩ-cm to approximately 10 kΩ-cm.

3. The semiconductor structure of claim 1, wherein said resistivity of said substrate is in a range from approximately 1 kΩ-cm to approximately 50 kΩ-cm.

4. The semiconductor structure of claim 1, wherein said substrate comprises a group IV substrate.

5. The semiconductor structure of claim 1, wherein said substrate comprises a silicon substrate.

6. The semiconductor structure of claim 1, wherein said spatially confined dielectric region is substantially centered under said at least one of said drain and said source.

7. The semiconductor structure of claim 1, wherein all sides of said spatially confined dielectric region are surrounded by said substrate.

8. The semiconductor structure of claim 1, wherein a top side of said spatially confined dielectric region is not covered by said substrate.

9. The semiconductor structure of claim 1, wherein said spatially confined dielectric region comprises silicon oxide.

10. The semiconductor structure of claim 1, wherein said substrate comprises a first substrate layer having said spatially confined dielectric region formed therein, and a second substrate layer situated over said first substrate layer and under said III-N HEMT.

11. The semiconductor structure of claim 1, wherein said substrate comprises a plurality of said spatially confined dielectric regions.

12. A semiconductor structure comprising:
a substrate having a resistivity of greater than or approximately equal to one kiloohm-centimeter (1 kΩ-cm);
a group III-N high electron mobility transistor (HEMT) including a source, a drain, and a gate, fabricated over said substrate;
a spatially confined dielectric region formed in said substrate, under at least one of said drain and said source;
said resistivity of said substrate and said spatially confined dielectric reducing a capacitive coupling of said at least one of said drain and said source to said substrate.

13. The semiconductor structure of claim 12, wherein said resistivity of said substrate is in a range from approximately 1 kΩ-cm to approximately 10 kΩ-cm.

14. The semiconductor structure of claim 12, wherein said resistivity of said substrate is in a range from approximately 1 kΩ-cm to approximately 50 kΩ-cm.

15. The semiconductor structure of claim 12, wherein said substrate comprises a group IV substrate.

16. The semiconductor structure of claim 12, wherein said spatially confined dielectric region is substantially centered under said at least one of said drain and said source.

17. The semiconductor structure of claim 12, wherein all sides of said spatially confined dielectric region are surrounded by said substrate.

18. The semiconductor structure of claim 12, wherein a top side of said spatially confined dielectric region is not covered by said substrate.

19. The semiconductor structure of claim 12, wherein said spatially confined dielectric region comprises silicon oxide.

20. The semiconductor structure of claim 12, wherein said substrate comprises a first substrate layer having said spatially confined dielectric region formed therein, and a second substrate layer situated over said first substrate layer and under said III-N HEMT.
